(19) United States
(12) Patent Application Publication
(10) Pub. No.: US 2018/0260059 A1
(43) Pub. Date: Sep. 13, 2018

(54) ARRAY SUBSTRATE, IN-CELL TOUCH SCREEN, AND DISPLAY DEVICE

(71) Applicants: BOE Technology Group Co., Ltd., Beijing (CN); Ordos Yuansheng Optoelectronics Co., Ltd., Inner Mongolia (CN)

(72) Inventor: Mingchao MA, Beijing (CN)

(21) Appl. No.: 15/801,863

(22) Filed: Nov. 2, 2017

(30) Foreign Application Priority Data
Mar. 7, 2017 (CN) 201720219596.3

(51) Int. Cl. G06F 3/041; H01L 27/12; H01L 29/786; G06F 3/044; G06F 3/047

(52) U.S. Cl. CPC G06F 3/0412; H01L 27/124; H01L 27/1222; G02F 1/1368; G06F 3/044; G06F 3/047; H01L 29/78675

(57) ABSTRACT

An array substrate, an in-cell touch screen, and a display device are provided. The array substrate includes: gate lines and data lines crossing each other; an array of pixels defined by the gate lines and the data lines, wherein a pixel electrode arranged in each pixel is connected with the gate line and the data line through a thin film transistor; and a plurality of touch electrodes arranged in an array, each of the touch electrodes being connected with the data line through a via-hole, wherein the touch electrodes are transparent electrodes; and wherein the data line is configured to output either a touch signal or a display signal at a time, wherein the display signal is transmitted to the pixel electrode through the thin film transistor, and the touch signal is transmitted to the touch electrode through the via-hole.

### CROSS-REFERENCES TO RELATED APPLICATIONS

This application claims priority to Chinese patent application No. 201720219596.3 filed on Mar. 7, 2017, which is incorporated herein by reference in its entirety.

### FIELD

The present disclosure relates to the field of display technologies, and particularly to an array substrate, an in-cell touch screen, and a display device.

### BACKGROUND

Among flat panel display devices, a Thin Film Transistor-Liquid Crystal Display (TFT-LCD) has become predominant in the existing market of flat panel displays, and widely applied to mobile products, e.g., a mobile phone, a flat panel computer, etc., due to its small volume, low power consumption, low production cost, no radiation, and other characteristics. At present, consumers have become not satisfied with the pure display function of the flat panel displays, and there is a growing demand of a light-weighted and thin TFT-LCD with a touch function. The more interesting and intuitive touch panel technology has become focused upon in the industry.

In the prior art, the TFT-LCD with the touch function is categorized into an on-cell touch display, and an in-cell touch display, where the touch screen of the on-cell touch display needs to be interposed between a color filter and a polarizing sheet of the display screen, so when there is a touch on the touch screen, then the problem of color non-uniformity may easily occur; and the volume of the product is large, and there is a complicated process of the product, thus resulting in a high cost thereof; and the in-cell touch display can have the display function integrated with the touch function, and the overall thickness of the device becomes smaller, so there is a promising application prospect thereof, but the existing in-cell touch display in which the display function is integrated with the touch function has a smaller opening-to-pixel-ratio, a low transmittivity of light rays, and thus lower brightness than those of a normal display, thus degrading the quality of a picture displayed on the in-cell touch display.

### SUMMARY

An embodiment of the disclosure provides an array substrate including: gate lines and data lines crossing each other; an array of pixels defined by the gate lines and the data lines, wherein a pixel electrode arranged in each pixel is connected with the gate line and the data line through a thin film transistor; and a plurality of touch electrodes arranged in an array, each of the touch electrodes being connected with the data line through a via-hole, wherein the touch electrodes are transparent electrodes; and wherein the data line is configured to output either a touch signal or a display signal at a time, wherein the display signal is transmitted to the pixel electrode through the thin film transistor, and the touch signal is transmitted to the touch electrode through the via-hole.

An embodiment of the disclosure provides an in-cell touch screen including the array substrate above.

An embodiment of the disclosure provides a display device including the in-cell touch screen above.

### BRIEF DESCRIPTION OF THE DRAWINGS

FIG. 1 is a schematic structural diagram of an array substrate according to an embodiment of the disclosure;

FIG. 2 is another schematic structural diagram of an array substrate according to an embodiment of the disclosure;

FIG. 3 is a schematic diagram of a touch electrode with a hollow design in the array substrate according to the embodiment of the disclosure; and

FIG. 4 is a schematic sectional view of the array substrate along line A-A in FIG. 3 according to the embodiment of the disclosure.

### DETAILED DESCRIPTION OF THE EMBODIMENTS

In order to make the objects, technical solutions, and advantages of the embodiments of the disclosure more apparent, the disclosure will be described below in further details with reference to the drawings, and apparently the embodiments described below are only a part but not all of the embodiments of the disclosure. Based upon the embodiments of the disclosure, all the other embodiments which can occur to those skilled in the art without any inventive effort shall fall into the scope of the disclosure.

The shapes and sizes of respective components in the drawings are not intended to reflect an actual proportion of the array substrate, but only intended to illustrate the content of the disclosure.

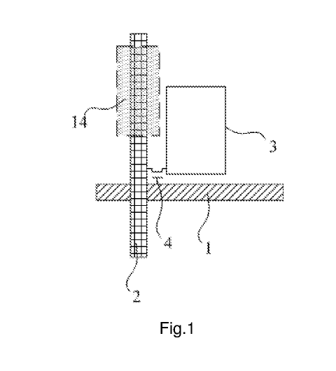

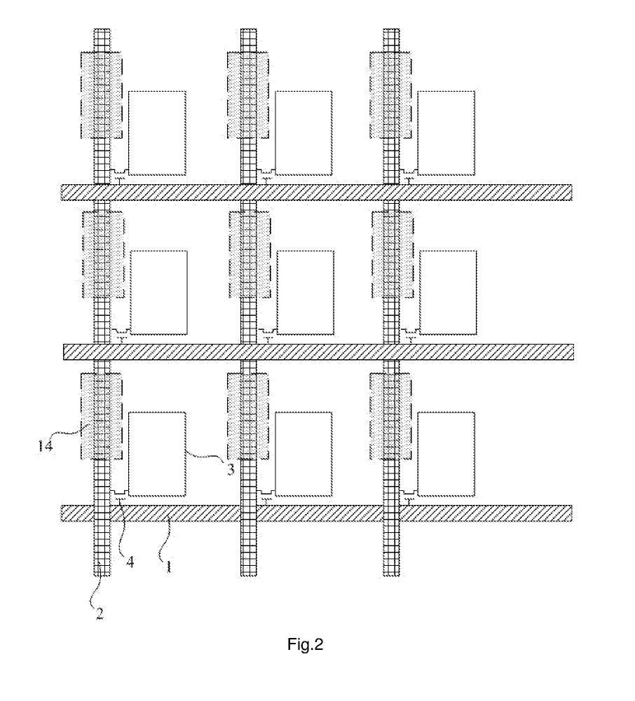

The embodiments of the disclosure provides an array substrate, as illustrated in FIG. 1 to FIG. 4, which includes: gate lines 1 and data lines 2 crossing each other; an array of pixels defined by the gate lines 1 and the data lines 2, where a pixel electrode 3 arranged in each pixel is connected with the gate line 1 and the data line 2 through a thin film transistor 4; and a plurality of touch electrodes 14 arranged in an array, each of the touch electrodes 14 is connected with the data line 2 through a via-hole 13, where the touch electrode is a transparent electrode; and each data line 2 outputs either a touch signal or a display signal at a time, where the display signal is transmitted to the pixel electrode 3 through the thin film transistor 4, and the touch signal is transmitted to the touch electrode through the via-hole 13.

The array substrate above includes the pixel electrodes 3 for performing the display function, and the touch electrodes 14 for performing the touch function, where each pixel electrode 3 is connected with the gate line 1 and the data line 2 through the thin film transistor 4, the touch electrodes 14 are arranged in an array, the touch electrodes 14 are connected with the data line 2 through the via-holes 13, and each data line 2 is configured to output either a touch signal or a display signal at a time. When touch operation, the thin film transistor 4 is turned off, and the data line 2 outputs the touch signal to the touch electrode 14 through the via-hole 13 to perform the touch function; and when displaying, the thin film transistor 4 is turned on, and the data line 2 outputs the display signal to the pixel electrode 3 through the thin film transistor 4 to perform the display function. Since the touch electrode 14 is a transparent electrode, an opening-to-pixel-ratio may not be affected, so the touch function can be performed in touch and sensing area including the touch electrodes 14 of the array substrate without affecting the opening-to-pixel-ratio thereof, and the touch electrodes 14 can be connected with the data lines 2 simply through the via-holes 13, thus simplifying a fabrication process thereof.

In some embodiments, the plurality of touch electrodes 14 are arranged in the extension direction of each data line 2, where the touch electrodes 14 are located above the data line 2, and their positive projections onto the data line 2 overlap with the data line 2.

In some embodiments, the array substrate further includes a driver IC, electrically connected with the data lines 2, configured to control the data lines to output a touch signal or a display signal.

In the array substrate above, the display function and the in-cell touch function are performed using a timing control unit of the driver IC. In the array substrate, the data lines 2 are connected with the touch electrodes 14 to form transparent touch areas in which a touch is sensed, and the data lines 2 are electrically connected with the driver IC, so that the touch and display functions are integrated, and the driver IC outputs a corresponding timing signal as needed for the touch or display function, that is, in order to perform the display function, the data lines 2 output a display signal, and in order to perform the touch function, the data lines 2 output a touch signal; and the display signal is output on the data lines 2 in a display stage, and the touch signal is output on the data lines 2 in a touch stage, where this process can be performed simply using the timing control unit in the driver IC to thereby switch between the normal display and touch functions simply and conveniently while controlling the timing precisely.

In some embodiments, the touch electrodes 14 can be made of transparent ITO.

In the array substrate above, the transparent electrode can be made of a transparent material, e.g., transparent indium tin oxide (ITO), or another material enabling the transparent electrode to perform its function. Since the touch electrodes are the transparent electrodes, an opening-to-pixel-ratio may not be affected, so the touch function can be performed in the touch and sensing areas including the touch electrodes 14 of the array substrate without affecting the opening-to-pixel-ratio thereof.

In some embodiments, the thin-film transistor 4 is structured with a top gate.

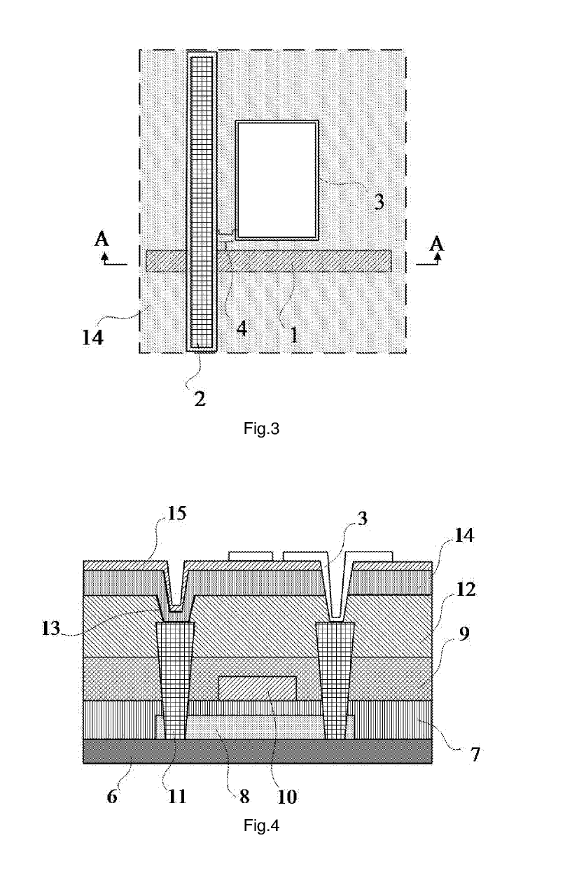

As illustrated in FIG. 1, FIG. 3, and FIG. 4, in some embodiments, the array substrate includes an underlying substrate 6, and a poly-silicon layer 8, a first insulation layer 7, a first metal layer 10, a second insulation layer 9, a second metal layer 11, a third insulation layer 12, the touch electrodes 14, a fourth insulation layer 15, and the pixel electrodes 3 formed successively, where the first metal layer 10 is used for forming the gate lines 1, the second metal layer 11 is used for forming the data lines 2, a plurality of touch electrodes 14 are arranged in the extension direction of the data lines 2, and the touch electrodes 14 are connected with the second metal layer 11 through the via-holes 13.

In some embodiments, the area of the touch electrode 14 is adjustable. The touch electrode 14 may overlap with the data line 2 and the pixel electrode 3. As illustrated in FIG. 3, the touch electrode 14 is designed hollow at its part overlapping with positive projection of the pixel electrode 3.

In some embodiments, as illustrated in FIG. 3, the touch electrode 14 is designed hollow at its part overlapping with positive projection of the data line 2 except its connection with the via-hole 13.

In the array substrate above, the thin-film transistor 4 is structured with a top gate, and desirable patterns are formed through exposure, development, etching, and stripping so that the poly-silicon layer 8, the first insulation layer 7, the first metal layer 10, the second insulation layer 9, the second metal layer 11, the third insulation layer 12, the touch electrodes 14, the fourth insulation layer 15, and the pixel electrodes 3 are formed successively on the underlying substrate, where the first metal layer 10 is used for forming the gate lines 1, the second metal layer 11 is used for forming the data lines 2, and the third insulation layer 12 is formed on the data lines 2 so that parts thereof for forming the touch areas come into contact with the touch electrodes 14 through the via-holes 13, thus resulting in a plane of the sensing areas. The touch electrodes 14 are designed hollow at their parts overlapping with the positive projections of the pixel electrodes 3, and the transparent electrodes 14 are designed hollow at their parts overlapping with the positive projections of the data lines 2 except their connections with the via-holes 13, so that the touch and sensing areas between the respective pixels in the transverse direction are disconnected, and the touch and sensing areas connected by the respective data lines 2 in the longitudinal direction are disconnected somewhere. The touch electrodes 14 are designed hollow at their parts overlapping with the positive projections of the data lines 2 and pixel electrodes 3, thus lowering a coupling capacitance in the display function so as to reduce coupling interference between different signals.

Some embodiments of the disclosure provide an in-cell touch screen including the array substrate according to any one of the embodiments above. Since the touch function can be performed in touch and sensing area including the touch electrodes 14 of the array substrate without affecting the opening-to-pixel-ratio thereof, there is a high product quality of the in-cell touch screen including the array substrate.

Some embodiments of the disclosure provide a display device including the in-cell touch screen above. Since there is a high product quality of the in-cell touch screen, there is a high product quality of the display device including the in-cell touch screen.

Since the touch electrodes 14 are connected to the data lines through the via-holes 13, when displaying, the data line 2 in each pixel element may be different, so the transverse touch electrodes 14, i.e., the transparent electrodes above the data lines, need to be disconnected, thus preventing interference on the different data lines 2 in the normal display function; and when touching, the data lines 2 output the touch signal to the touch electrodes to perform the touch function. In order for a precise touch in the longitudinal direction, and the strength of a signal sensed for the touch, the touch electrodes 14 need to be disconnected in the longitudinal direction according to the resolution of the pixels, that is, they are divided into several upper and lower touch blocks, where the parts of the touch electrodes 14 overlapping with the data liens 2 and the pixel electrodes 3 can be designed hollow to thereby reduce coupling interference between different signals.

Evidently those skilled in the art can make various modifications and variations to the disclosure without departing from the spirit and scope of the disclosure. Thus the disclosure is also intended to encompass these modifications and variations thereto so long as the modifications and variations come into the scope of the claims appended to the disclosure and their equivalents.

1. An array substrate, comprising:
gate lines and data lines crossing each other;
an array of pixels defined by the gate lines and the data lines, wherein a pixel electrode arranged in each pixel is connected with the gate line and the data line through a thin film transistor; and
a plurality of touch electrodes arranged in an array, each of the touch electrodes being connected with the data line through a via-hole, wherein the touch electrodes are transparent electrodes;
wherein the data line is configured to output either a touch signal or a display signal at a time, wherein the display signal is transmitted to the pixel electrode through the thin film transistor, and the touch signal is transmitted to the touch electrode through the via-hole.

2. The array substrate according to claim 1, wherein the plurality of touch electrodes are arranged in the extension direction of each data line, the touch electrodes are located above the data line, and positive projections of the touch electrodes onto the data line overlap with the data line.

3. The array substrate according to claim 1, wherein the array substrate further comprises a driver IC, wherein the driver IC is electrically connected with the data lines, and is configured to control the data lines to output a touch signal or a display signal.

4. The array substrate according to claim 1, wherein the transparent electrodes are made of transparent ITO.

5. The array substrate according to claim 2, wherein the thin-film transistor is structured with a top gate.

6. The array substrate according to claim 5, wherein the array substrate comprises an underlying substrate, and a poly-silicon layer, a first insulation layer, a first metal layer, a second insulation layer, a second metal layer, a third insulation layer, the touch electrodes, a fourth insulation layer, and the pixel electrodes formed successively, wherein the first metal layer is used for forming the gate lines, the second metal layer is used for forming the data lines, the plurality of touch electrodes are arranged in the extension direction of the data lines, and the touch electrodes are connected with the second metal layer through the via-holes.

7. The array substrate according to claim 6, wherein the touch electrodes are designed hollow at their parts overlapping with positive projections of the pixel electrodes.

8. The array substrate according to claim 6, wherein the touch electrodes are designed hollow at their parts overlapping with positive projections of the data lines except their connections with the via-holes.

9. An in-cell touch screen, comprising an array substrate, wherein the array substrate comprises:
gate lines and data lines crossing each other;
an array of pixels defined by the gate lines and the data lines, wherein a pixel electrode arranged in each pixel is connected with the gate line and the data line through a thin film transistor; and
a plurality of touch electrodes arranged in an array, each of the touch electrodes being connected with the data line through a via-hole, wherein the touch electrodes are transparent electrodes;
wherein the data line is configured to output either a touch signal or a display signal at a time, wherein the display signal is transmitted to the pixel electrode through the thin film transistor, and the touch signal is transmitted to the touch electrode through the via-hole.

10. A display device, comprising an in-cell touch screen, wherein the in-cell touch screen comprises an array substrate, and the array substrate comprises:
gate lines and data lines crossing each other;
an array of pixels defined by the gate lines and the data lines, wherein a pixel electrode arranged in each pixel is connected with the gate line and the data line through a thin film transistor; and
a plurality of touch electrodes arranged in an array, each of the touch electrodes being connected with the data line through a via-hole, wherein the touch electrodes are transparent electrodes;
wherein the data line is configured to output either a touch signal or a display signal at a time, wherein the display signal is transmitted to the pixel electrode through the thin film transistor, and the touch signal is transmitted to the touch electrode through the via-hole.
